(19) United States
(12) Patent Application Publication
(10) Pub. No.: US 2018/0190847 A1
(43) Pub. Date: Jul. 5, 2018

(54) NON-ORTHOGONALLY PATTERNED MONOLITHICALLY INTEGRATED THIN FILM PV

(71) Applicant: Ascent Solar Technologies, Inc., Thornton, CO (US)

(72) Inventors: Joseph H. Armstrong, Littleton, CO (US); Stephanie Persha Retureta, Highland Ranch, CO (US); Ann Fitzgerald, Longmont, CO (US); Jerry Reichenberg, Lafayette, CO (US)

(73) Assignee: Ascent Solar Technologies, Inc., Thornton, CO (US)

(21) Appl. No.: 15/862,370

(22) Filed: Jan. 4, 2018

Related U.S. Application Data
(60) Provisional application No. 62/442,662, filed on Jan. 5, 2017.

(51) Int. Cl. H01L 31/0463; H01L 31/0465; H01L 31/0236; H01L 31/02

(52) U.S. Cl. CPC H01L 31/0463; H01L 31/0201; H01L 31/0236; H01L 31/0465

(57) ABSTRACT

A monolithically integrated flexible thin film photovoltaic device consisting of a plurality of sides having at least one side that is not orthogonal to the remaining sides, a series of isolation scribes along the periphery of the PV device that are parallel to the aperture sides, a plurality of cells patterned to have the same power generation area regardless of angle of the isolation scribes or the monolithic integration pattern.

### CROSS-REFERENCE TO RELATED APPLICATIONS

This application claims benefit of priority to U.S. Provisional Application Ser. No. 62/442,662 filed Jan. 5, 2017, which is incorporated herein by reference.

### BACKGROUND OF THE INVENTION

The present invention is in the technical field of thin film photovoltaics and solar arrays.

Typically, solar arrays in architectural applications (such as solar panels on a roof) utilize an orthogonal type or rectangular pattern. However, many terrestrial, military, and aerospace applications also utilize or are seeking a non-orthogonal (or angled) array type solar solution. Such usage is typically applied to minimize mass and stowage volume. Traditional crystalline photovoltaic (PV) cells, either monocrystalline or polycrystalline, as well as rigid thin film PV modules, can pose challenging to meet the need in this industry. Further, non-orthogonal arrays do not optimize utilization of rectangular or square patterned PV for there is wasted area where no power is generated. As rectangular or square patterned PV increases in size to reduce installation time and cost, the area of the installation that is not generating power also increases.

### SUMMARY OF THE INVENTION

The present invention is a monolithically integrated thin film solar module for use in non-orthogonal applications. While this invention has been developed specifically for applicant's flexible thin film monolithically integrated CIGS technology, it can equally be applied to rigid monolithically integrated but with a greater degree of difficulty. Details with regard to the actual patterning between cells can be found elsewhere (U.S. Pat. No. 8,716,591 “Array of Monolithically Integrated Thin Film Photovoltaic Cells and Associated Methods”), but is briefly described herein. Applicant's process relies on all of the thin film layers to be deposited prior to patterning. Patterning of the thin film stack defines individual cells, and subsequent printing interconnects creates the string of cells that is referred to as a module. The design of a module requires that the performance of individual cells are matched as closely as possible in both voltage and current performance. Chemistry of the PV cells dictates the voltage, and the area exposed to sunlight determines the amount of current produced. By virtue of the large-area thin film deposition technology, the chemistry of the patterned cells still retains the same chemistry, and thus, all cells are virtually the same voltage. Thus, for the best performance module, the patterned cells should have virtually the same area to generate the same current.

A process that isolates and defines the outside of the power generating area, referred to as isolation scribes, prevents power leakage outside the module or potential electrical shorting of the PV to areas outside the module. Nominally, patterning of the individual cells and the isolation scribes are either parallel to, or normal, to the other scribes. Thus, for a ‘traditional’ orthogonal thin film PV module, the active area of each cell, that is, the area actively producing electrical power, is thereby identical by virtue of each cell having the same width, or pitch (spacing between cells) and width (the width inside the isolation scribe area) and the orthogonal relationship between these scribes.

In the present invention, the restrictions of orthogonality is removed to best maximize the available area for power generation. As was the case before, the solar module of the present invention comprises individual solar cells in series, but as the orthogonality restriction has been removed, the cell pitch and width must be optimized to ensure that each cell has the same active area to generate a balanced current, to maximize performance. The grid pattern for each solar cell may be optimized to maximize power transfer between cells in a monolithic string. Further, the solar module of the present invention can be patterned to have more than the traditional four sides without compromise in performance, and the width of the cells may increase or decrease systematically, or in extreme cases, change randomly, provided that the cell pitch change in accordance with maintaining the same area, and thus, current generation. Thickness of the back contact and the shape and width of top metallic grids may need to be adjusted accordingly as the current of narrower cells will still be generating the same current as the wider cells.

### BRIEF DESCRIPTION OF THE DRAWINGS

Other advantages of the present invention will be readily appreciated, as the same becomes better understood by reference to the following detailed description when considered in connection with the accompanying drawings wherein:

FIG. 1, is a top view of a polycrystalline silicon solar cell;

FIG. 2 is a top view of a monolithically integrated PV module with orthogonal relationship between all of the scribes;

FIGS. 3-6, illustrate the manufacturing process of the present invention;

FIGS. 4-6 illustrate cross sectional views of the PV module/present invention during the monolithic integration phase of the manufacturing process;

is a FIG. 7 is a top view of an embodiment of the present invention (trapezoidal);

FIG. 8 is a top view of an embodiment of the present invention (rhomboid);

FIG. 9 is a top view of an embodiment of the present invention (>4 sides); and

FIG. 10 is a top view of an implementation of a plurality of embodiments of the present invention.

FIG. 11 is a view of an embodiment of the present invention where the module is a multifaceted construction while maintaining proper current balance.

### DETAILED DESCRIPTION OF THE INVENTION

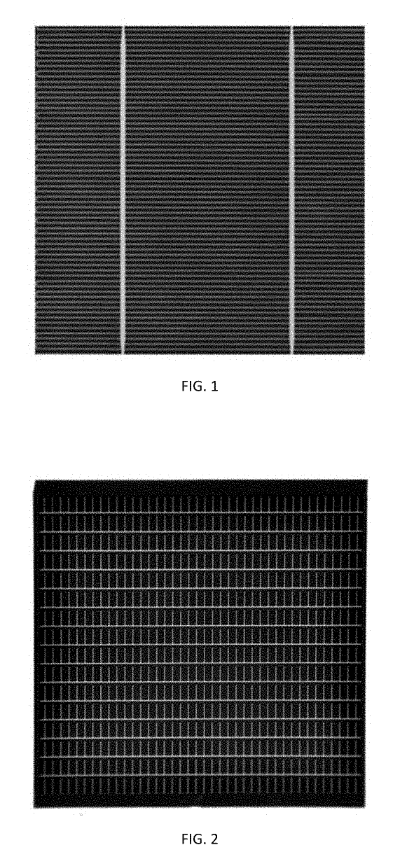

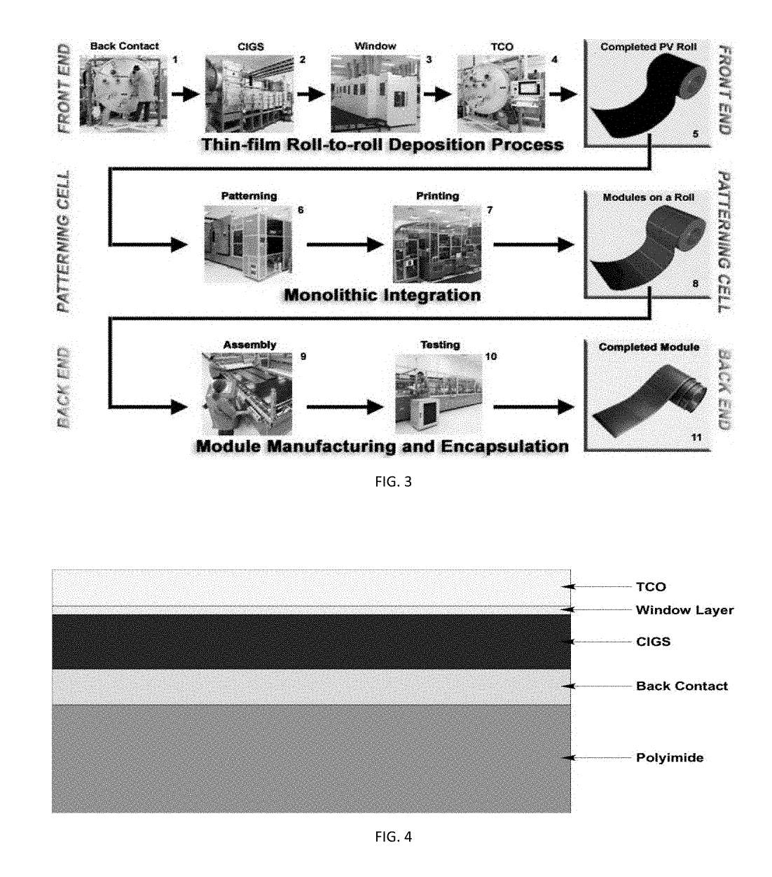

Photovoltaic cells, commonly referred to as solar cells, generate electrical power when these devices are illuminated with sunlight and are connected to an appropriate electrical load. As the individual solar cells generate only a small voltage (nominally 0.5 volts), the solar cells are connected in series where the voltage adds together. For optimum performance, the individual solar cells are matched for electrical output, with the areas of each cell being matched at a minimum. The prior art with crystalline solar cells (FIG. 1) involves the cells being interconnected via soldering or welding and placed in a mechanical/environmental package. Due to the fragility of the prior art solar cells, these packages are often rigid, and to maximize the amount of power generated within this package, the shape of this package reflects the type of cells, namely each side being at right angles to adjacent sides. With references to the Figures and accompanying Attachments, the present invention describes a photovoltaic (PV) module comprised of a plurality of individual cells patterned and interconnected during monolithic integration processing. FIG. 2 shows a PV module formed by monolithic integration that is of comparable size to the prior art crystalline solar cell shown in FIG. 1. The main difference is that unlike the 0.5 volts generated by the cell in FIG. 1, the module in FIG. 2 consists of sixteen (16) solar cells patterned and monolithically interconnected into a string that generates 9.0 volts. The cells patterned in the module shown in FIG. 2 are rectangular, albeit individually much smaller than the cell shown in FIG. 1. Because each cell has the same height (or pitch) and same width (defined by the module width), each cell has the same rectangular shape and area, and the shape of the module is also rectangular with dimensions based on the plurality of solar cells in the assembly.

The monolithically integrated module in FIG. 2 was specifically designed to generate the 9.0 volts open circuit that was required for a power regulation circuit that generated a universal serial bus (USB) power circuit for charging portable electronic devices. In this manner, additional power can easily be provided by connecting these monolithically integrated modules in parallel, with each module having the same voltage but the current (and thus the power) increasing linearly with each additional module added.

Regarding larger PV modules, constructed with discrete solar cells (FIG. 1) or with monolithically integrated modules (FIG. 2), the ideal assembly consists of matched cells of the same nominal electrical performance, as any higher performing devices within the assembly are not fully utilized.

However, the solar cells do not need to be the same shape to provide the electrical performance of the cells is matched. With regard to thin film monolithically integrated modules, that has uniform deposition over the given area, matching cells nominally refers to matching the actual power. As stated earlier, the cells patterned into a rectangular or square shape as shown in FIG. 2 automatically matches the cell areas when cells have the same width. If such a monolithically integrated module had one side that was non-orthogonal, or at an angle, with respect to the other sides, as long as the cell areas could be matched, the performance of the resultant module should be optimized within the aperture area of the module as defined by the isolation scribes noted before.

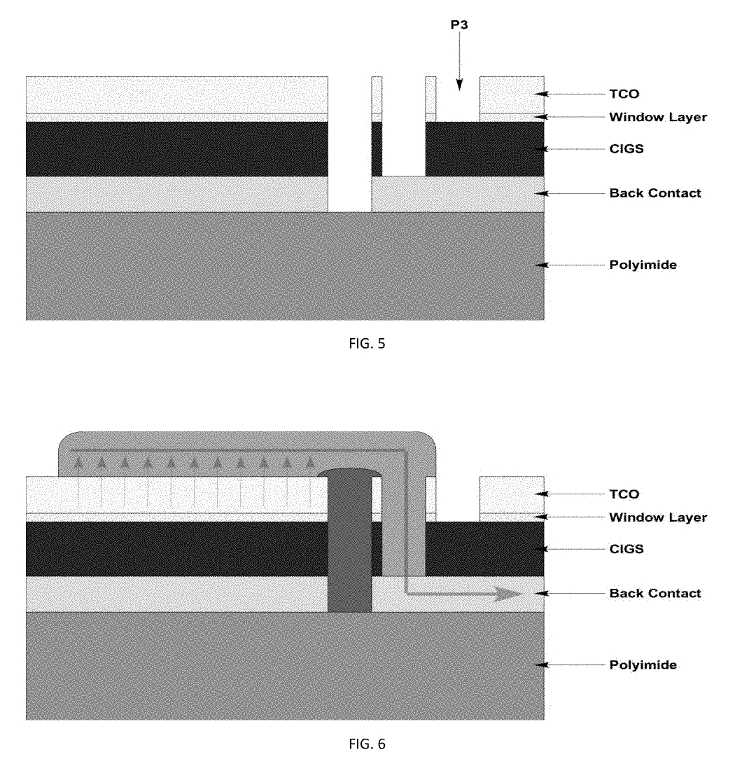

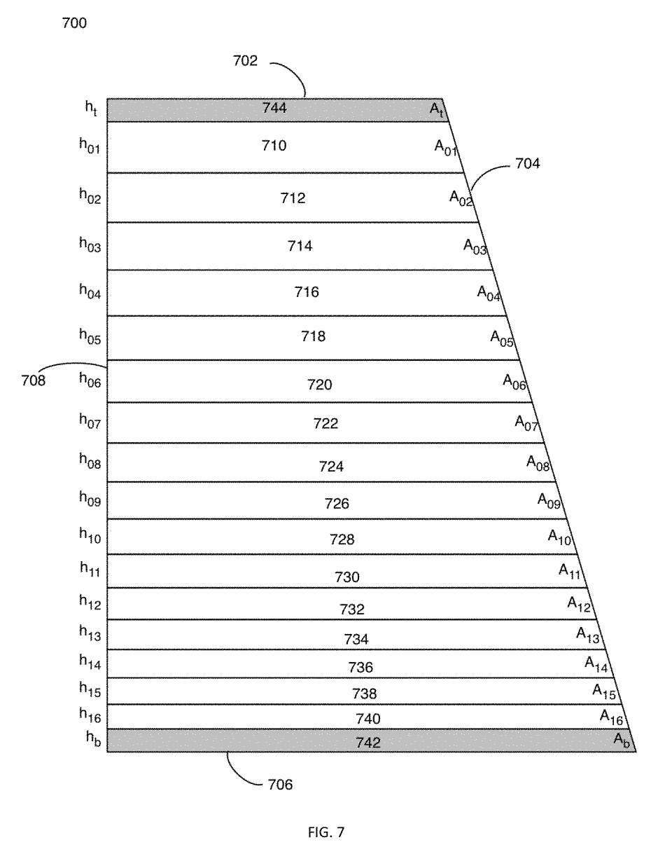

In general, the non-orthogonal PV module is formed by the process outlined in FIG. 3 illustrating the thin film roll to roll (“R2R”) deposition, the monolithic integration (patterning and printing), and PV module manufacturing and encapsulation phases. As noted in FIG. 3, all of the thin film deposition steps are completed in the first phase of the manufacturing process, thereby providing a ‘clean slate’ for the patterning and printing steps to follow. These thin film stacks are then patterned into individual cells; in various embodiments, the patterning can be achieved by laser scribing, mechanical scribing, charged particle etching, etc. The final phase in FIG. 3 refers to packaging of final products that are not germane to this discussion. Patterning of the PV module consists of two main types of scribe, the first being an isolation scribe that defines the outside of the module and prevents electrical power from bleeding out the physical edges of the cut module. The second scribe operation consists of three types of scribes that define the basis for monolithically integrating these individual cells. Thus, applicant's process uses four types of scribes throughout its construction. FIGS. 4-6 show the cross-sectional view of the PV module during the Monolithic Integration phase of the process. Note that these figures represent a simplistic view of the scribe patterning to illustrate the approach more easily. FIG. 4 represents the cross section of the thin film stack as completed during the first phase of our process shown earlier in FIG. 3. FIG. 5 is an illustrative example of the patterning laser scribe sequence in the monolithic integration process, whereby the P1 scribe isolates the back contact of each solar cell, the P2 scribe, or via scribe, provides a passage to the back contact of the adjacent solar cell, and P3 is the isolation scribe of the top contact of the thin film stack, in this case defined by the transparent conductive oxide (or TCO). Subsequent printing of an insulator and metallic conductive finger/interconnect connects these patterned cells into a prescribed series interconnect (FIG. 6). While, by definition, the scribe set consisting of one P1, P2, and P3 scribe must be in parallel in order to achieve the desired monolithic interconnect between adjacent cells, the orientation of the P1/P2/P3 scribe set between each cell set can be in different orientation with respect to other P1/P2/P3 scribe sets, the isolation scribes, or both. Separation and the relative angle between adjacent P1/P2/P3 scribe sets can vary, provided that the active area of each defined cell must be the same. In addition to the scribe sets, changes must be made to the grid pattern to ensure that the monolithic interconnect through the P2 scribe is complete and that finger spacing reduces the potential ohmic losses when current must be carried through the TCO a longer distance than elsewhere in the device.

Positive and negative terminals are formed on either end of the module, where multiple P2 scribes expose the back contact and enables the screen printed pads to be printed and connect down to the metallic contact layer. The area of these parts of the module are not relevant to the current matching discussion as this portion of the module does not contribute to PV power generation. However, the area of these pads must be sufficient to handle the current generated by the module without excessive ohmic losses.

Given that the isolation scribes and P1/P2/P3 scribe sets are not orthogonal to one another in the present invention, the resulting shape could be more than a four-sided module. In the embodiments shown in FIGS. 7-10, a total of sixteen (16) cells are monolithically connected in series; however, the cell count can vary from one to a plurality defined by maximized performance of the module. As the area defined by the P1/P2/P3 scribe set does not contribute to PV power generation, a higher cell count results in smaller cell area, where eventually the cell area is comparable to the P1/P2/P3 scribe area.

The resultant non-orthogonal PV module may be further appreciated when referring to exemplary embodiments. In a first embodiment, as shown in FIG. 7, the PV module 700 is defined as a trapezoidal configuration by isolation scribes 702, 704, 706, and 708 comprising four sides, with one side being non-orthogonal to the other sides, and a plurality of sixteen (16) cells 710, 712, 714, 716, 718, 720, 722, 724, 726, 728, 730, 732, 734, 736, 738, and 740 in series, framed by positive 742 and negative 744 terminals on opposite ends of the plurality of cells. The area for each of the cells (A01 to A16) is matched to maintain current balance by adjusting cell height (or pitch). More specifically the cell heights h0-h16 are not equal/identical. In this embodiment the scribe sets P1/P2/P3 (not numbered), illustrated simply as a single line between cells, are oriented parallel to one another.

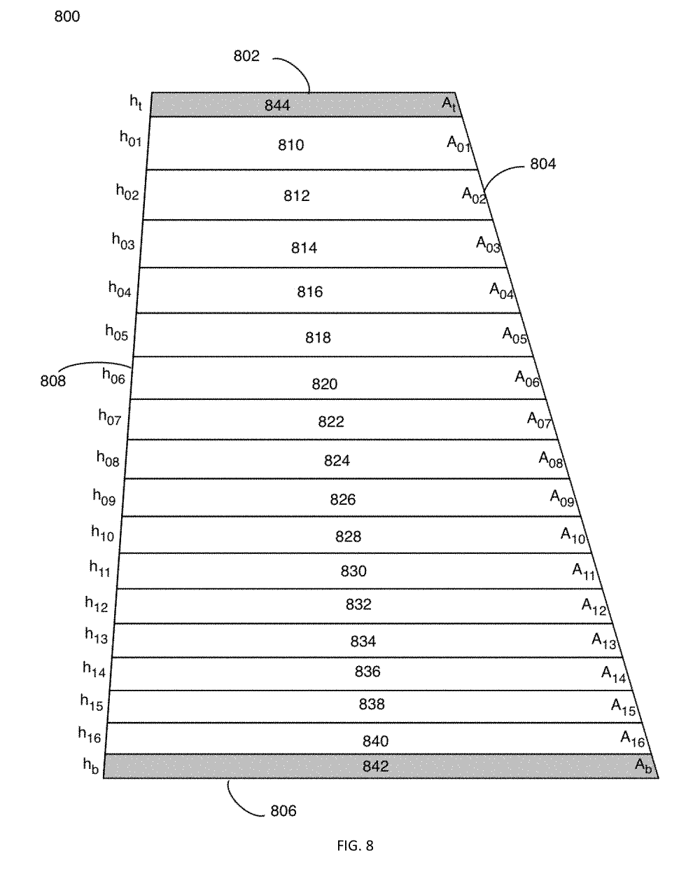

In a second embodiment, shown in FIG. 8, the PV module 800 is a rhomboid configuration, defined by isolation scribes 802, 804, 806, and 808 whereby parallel sides 802 and 806 are not the same length and the other sides 804 and 808 can be of different length and angle. As was the case in the first embodiment, all of the P1/P2/P3 scribe sets are oriented parallel to one another and the cell height (or pitch) is adjusted for each cell to ensure the cell area is the same for each cell.

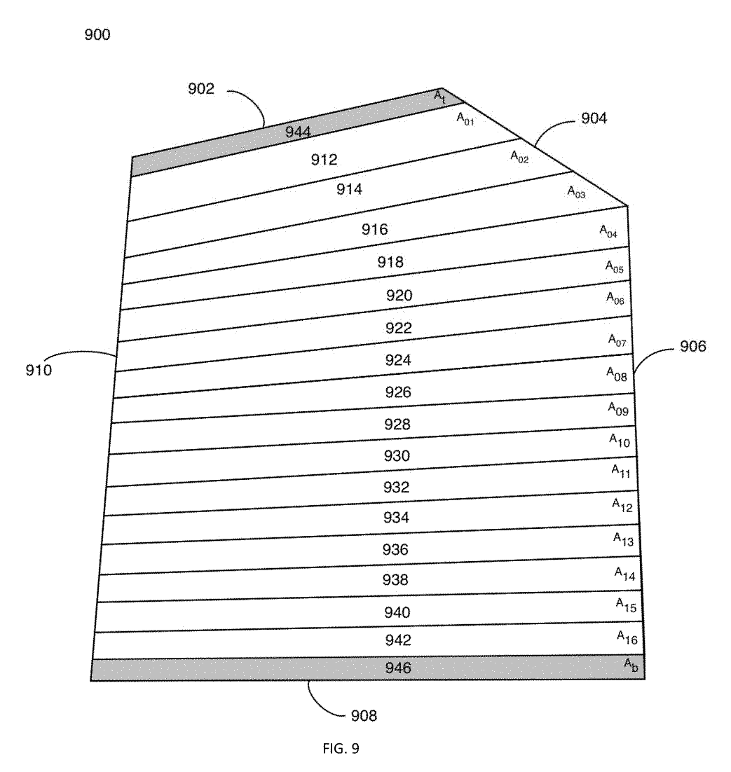

In a third embodiment, shown in FIG. 9, the PV module 900 is a non-orthogonal shape having a pattern of more than the traditional four sides that are defined by isolation scribes 902, 904, 906, 908 and 910. However, as the P1/P2/P3 scribe sets are clearly not oriented in parallel to one another, the typical definition of cell height (pitch) includes both the dimensional separation and the angle of the scribe set must be adjusted to maintain equal active areas of each cell.

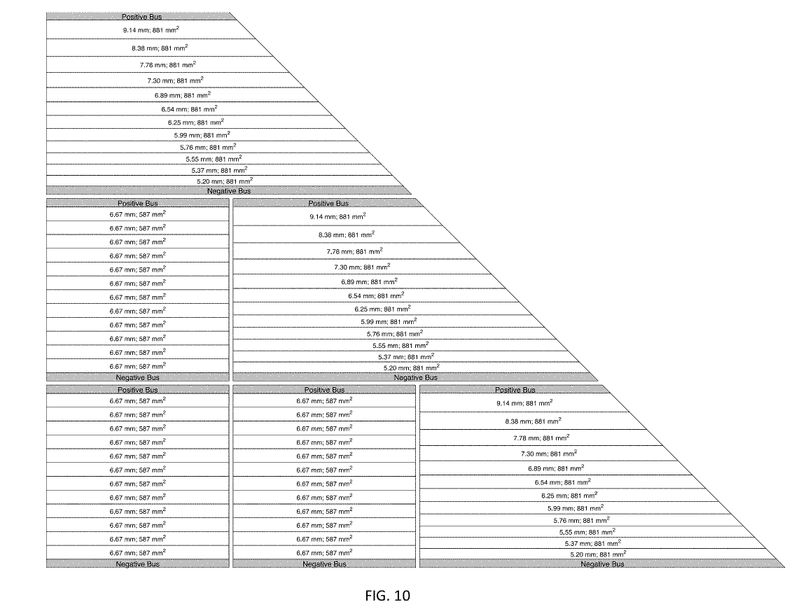

FIG. 10 is an illustrative example of an implementation of a plurality of PV modules, of varying shapes (orthogonal and non-orthogonal). In this embodiment, the cell height (pitch) is adjusted to ensure the cell area is the same for each cell and the number of cells in each module is identical to ensure the same voltage with each module.

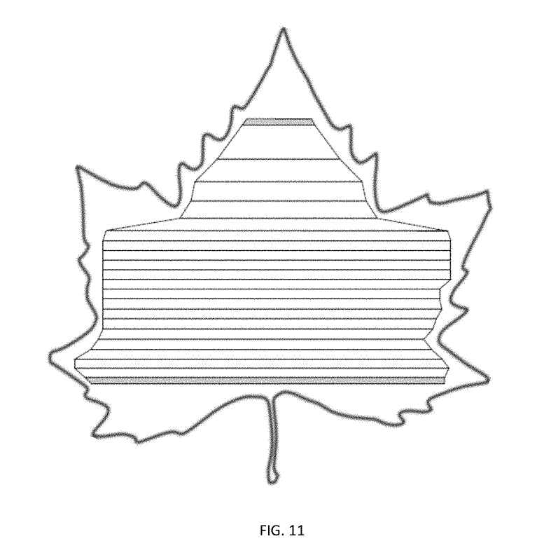

FIG. 11 is another illustrative example of an implementation whereby the PV module is a multifaceted definition of cells of various widths, still based on having a balanced area for current generation. In this embodiment, the possible shape combinations and orientations are only limited by the patterning technology in order to provide a maximum area coverage of photovoltaic material within the selected package, in this embodiment, for a leaf pattern.

While the foregoing written description of the invention enables one of ordinary skill to make and use what is considered presently to be the best mode thereof, those of ordinary skill will understand and appreciate the existence of variations, combinations, and equivalents of the specific embodiment, method, and examples herein. The invention should therefore not be limited by the above described embodiment, method, and examples, but by all embodiments and methods within the scope and spirit of the invention.

What is claimed is:

1. A monolithically integrated flexible thin film PV device comprising:
a plurality of sides with at least one side that is not orthogonal to the remaining sides;
a series of isolation scribes along the periphery of the PV device;
a plurality of cells patterned during a monolithic integration process that shall have the same power generation area, regardless of the angle of the isolation scribes or monolithic integration pattern; and
two bus bars separated by at least one side of the PV device on either end of the plurality of cells that serves as positive and negative terminals of the device.

2. The device of claim 1 further comprising three or more isolation scribes along the periphery of the PV device that are parallel to the plurality of sides that define an aperture area.

3. The device of claim 1, wherein the PV device is defined by the isolation scribes as a trapezoidal configuration, with one side being non-orthogonal to the other sides.

4. The device of claim 1, wherein the PV module is a multifaceted definition of cells of various widths.

5. A method to manufacture a monolithically integrated flexible thin film PV device by
utilization of a series of four or more isolation scribes along the periphery of the PV device that are parallel to the plurality of sides that define an aperture area;
patterning a plurality of cells during a monolithic integration process that shall have the same power generation area, regardless of the angle of the isolation scribes or monolithic integration pattern; and
the application of two bus bars separated by at least one side of the PV device on either end of the plurality of cells that serves as positive and negative terminals of the device.
